(19) United States
(12) Patent Application Publication
(10) Pub. No.: US 2009/0114940 A1
(43) Pub. Date: May 7, 2009

(54) Light-Emitting Device

(75) Inventors: Chih-Chung Yang, Taipei City (TW); Dong-Ming Yeh, Taipei City (TW); Cheng-Yen Chen, Taipei City (TW); Yen-Cheng Lu, Taipei City (TW); Kun-Ching Shen, Taipei City (TW); Chi-Feng Huang, Taipei City (TW)

Correspondence Address: QUINTERO LAW OFFICE, PC, 2210 MAIN STREET, SUITE 200, SANTA MONICA, CA, 90405, US

(73) Assignee: NATIONAL TAIWAN UNIVERSITY, Taipei (TW)

(21) Appl. No.: 12/055,119

(22) Filed: Mar. 25, 2008

(30) Foreign Application Priority Data
Nov. 1, 2007 (TW) TW96141173

(51) Int. Cl. H01L 33/00

(52) U.S. Cl. 257/99; 257/E33.063; 257/E33.025

(57) ABSTRACT

The invention provides a light-emitting device, comprising a light-emitting element and a surface plasmon coupling element connected to the light-emitting element. In an embodiment of the invention, the surface plasmon coupling element comprises a dielectric layer connected to the light-emitting element and a metal layer on the dielectric layer. In another embodiment of the invention, the light-emitting device is a light-emitting diode, comprising an active layer between an n-type semiconductor layer and a p-type semiconductor layer, and a surface plasmon coupling element adjacent to the n-type semiconductor layer. In a further embodiment of the invention, a current spreading layer on a second type semiconductor layer of the light-emitting device includes a plurality of strip-shaped structures, and the surface plasmon coupling element is disposed on the current spreading layer and filled into the gap between the strip-shaped structures of the current spreading layer.

### BACKGROUND OF THE INVENTION

1. Field of the Invention

The invention relates to a light-emitting device and more particularly relates to a light-emitting diode.

2. Description of the Related Art

Semiconductor light-emitting devices have developed rapidly in many applications, for example liquid crystal display backlights. As such, semiconductor light-emitting devices may replace currently used illuminations, such as fluorescent lamps or light bulbs. Specifically, GaN based light-emitting diodes are the focus of white light sources and liquid crystal display backlights.

FIG. 1 shows the structure of a conventional InGaN based light-emitting diode, which sequentially includes a buffer layer 104, an n-GaN layer 106, an InGaN/GaN quantum well structure 108, a p-GaN layer 110 and a transparent conductive layer 112 on a substrate 102. A p-type electrode 114 connects the transparent conductive layer 112 and an n-type electrode 116 connects the n-GaN layer 106. When a current is applied to the light-emitting diode, electrons and holes are respectively generated in the n-GaN layer 106 and the p-GaN layer 110, and electron hole pairs are combined in the InGaN/GaN quantum well to generate photons. However, photons are easily reflected and trapped in the semiconductor to change into heat and only a few photon parts can be radiated out of the light-emitting diode. On the other hand, quantum efficiency of the InGaN based light-emitting diode is significantly reduced when wavelength exceeds 550 nm. Hence, it is important to enhance light intensity of light-emitting diodes in the long-wavelength visible range.

### BRIEF SUMMARY OF INVENTION

According to the issues described, the invention provides a method for enhancing lighting efficiency of a light-emitting diode by surface plasma coupling.

The invention provides a light-emitting device, comprising a light-emitting element and a surface plasmon coupling element connected to the light-emitting element. In an embodiment of the invention, the surface plasmon coupling element comprises a dielectric layer connected to the light-emitting element and a metal layer on the dielectric layer. In another embodiment of the invention, the light-emitting device is a light-emitting diode, comprising an active layer between an n-type semiconductor layer and a p-type semiconductor layer, and a surface plasmon coupling element adjacent to the n-type semiconductor layer. In a further embodiment of the invention, the light-emitting device comprises a first type semiconductor layer, an active layer on the first type semiconductor layer, a second type semiconductor layer on the active layer and a surface plasmon coupling element, a current spreading layer including a plurality of strip-shaped structures disposed on the second type semiconductor layer, and a surface plasmon coupling element disposed on the current spreading layer and filled into the gap between the strip-shaped structures of the current spreading layer.

### BRIEF DESCRIPTION OF DRAWINGS

The invention can be more fully understood by reading the subsequent detailed description and examples with references made to the accompanying drawings, wherein:

FIG. 1 shows the structure of a conventional InGaN based light-emitting diode.

FIG. 2 illustrates a mechanism for enhancing lighting efficiency of a light-emitting diode by surface plasmon coupling of an embodiment of the invention.

FIG. 3 shows a light-emitting device of an embodiment of the invention.

FIG. 4 shows photoluminescence as a function of wavelength of two LED examples including the LED of FIG. 3 and a conventional LED.

FIG. 5 shows a light-emitting device of another embodiment of the invention.

FIG. 6 shows electroluminescence as a function of current of three LED examples including the LED of FIG. 5, the LED of FIG. 3 and a conventional LED.

FIG. 7A˜7E shows a method for forming the light-emitting diode of FIG. 5.

FIG. 8 shows photoluminescence as a function of wavelength of three LED examples including the LED of FIG. 5 before annealing, the LED of FIG. 5 after annealing and a conventional LED.

FIG. 9A˜FIG. 9D illustrate process for fabricating a transmissive light-emitting device of an embodiment of the invention.

FIG. 10A˜FIG. 10E illustrate process for fabricating a reflective light-emitting device of another embodiment of the invention.

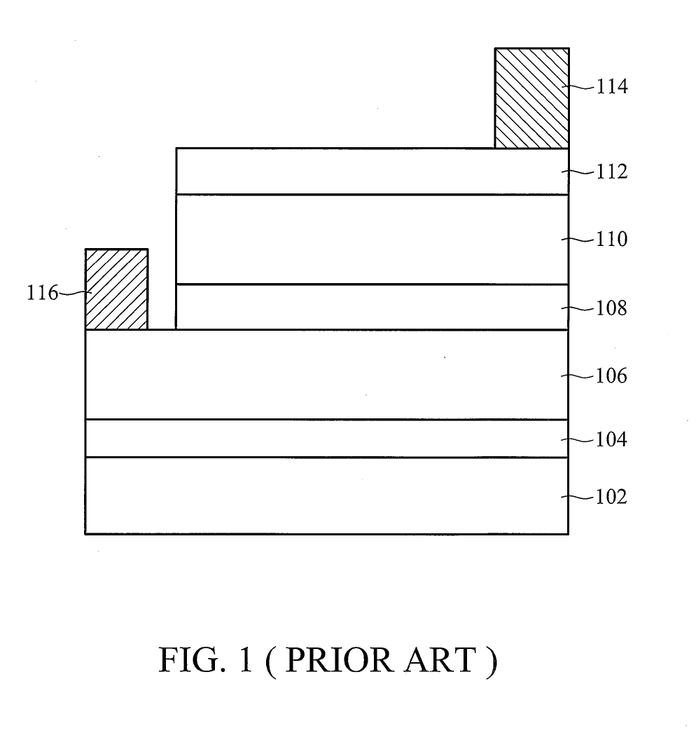

### DETAILED DESCRIPTION OF INVENTION

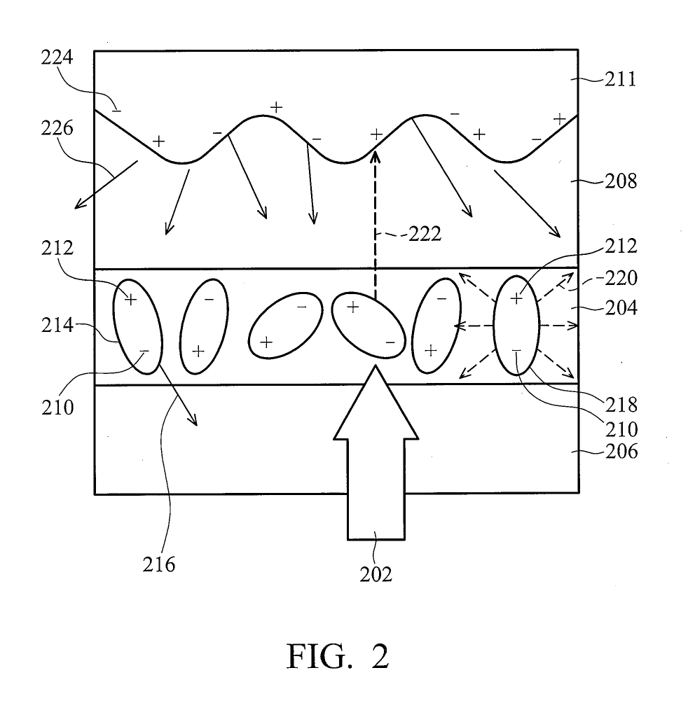

Referring to FIG. 2, which illustrates a mechanism for enhancing lighting efficiency of a light-emitting diode by surface plasmon coupling of an embodiment of the invention, an excitation 202, such as a current or laser, passes a bottom structure layer 206 of the light-emitting diode and injects into an active layer 204 to generate electrons 210 and holes 212. According to the design of the device structure, electrons 210 and holes 212 are then recombined in the active layer 204 to generate energy. Electrons 210 and holes 212 can be recombined in two ways, one is radiative recombination 214 and another is non-radiative recombination 218. Radiative recombination 214 generates photons 216 which are generally represented as light. Non-radiative recombination 218 generates phonons 220 which are generally represented as lattice vibration or heat. Most photons 216 are trapped in the structure layer and only a few parts can be radiated out of the light-emitting diode.

A light-emitting diode of an embodiment of the invention not only emits light by the recombination of electrons 210 and holes 212 in the quantum well, but also creates an alternative channel of light emission by the coupling 222 between an evanescent field of a surface plasmon 224 and the electric dipole in the active layer 204 to transfer the energy of electrons and holes into the surface plasmon 224 between the metal layer 211 and the top structure layer 208 for emitting light 226.

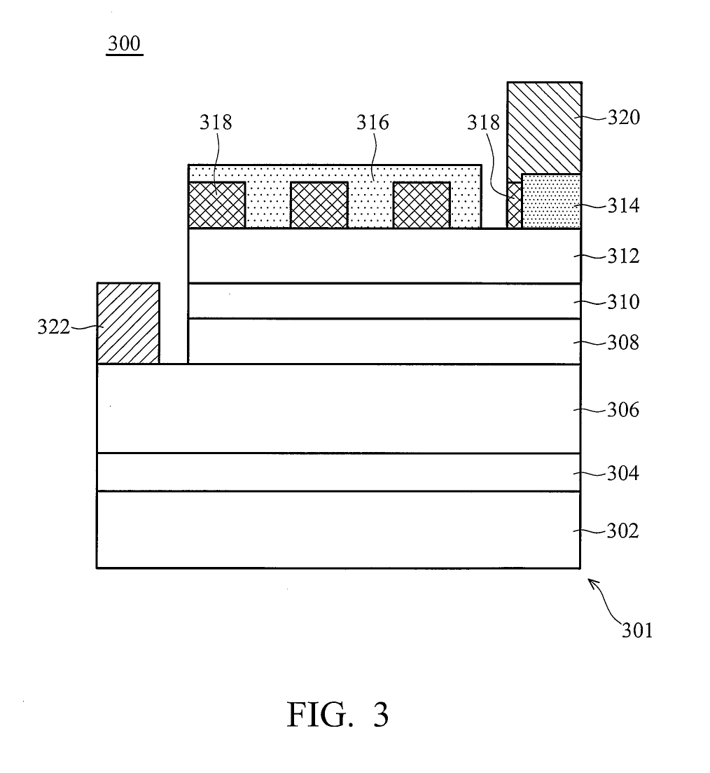

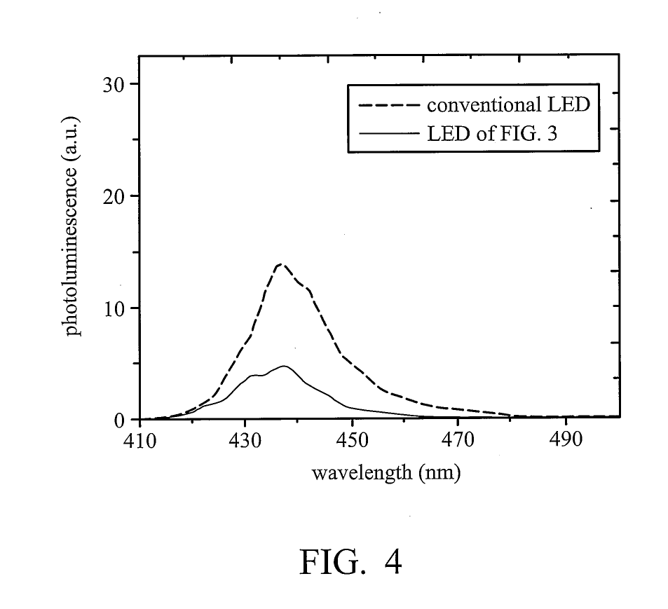

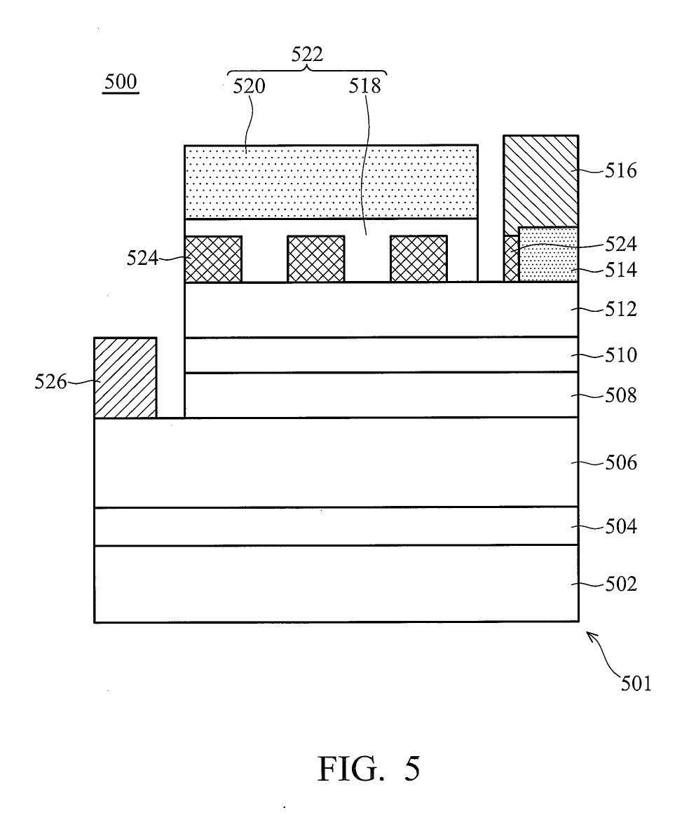

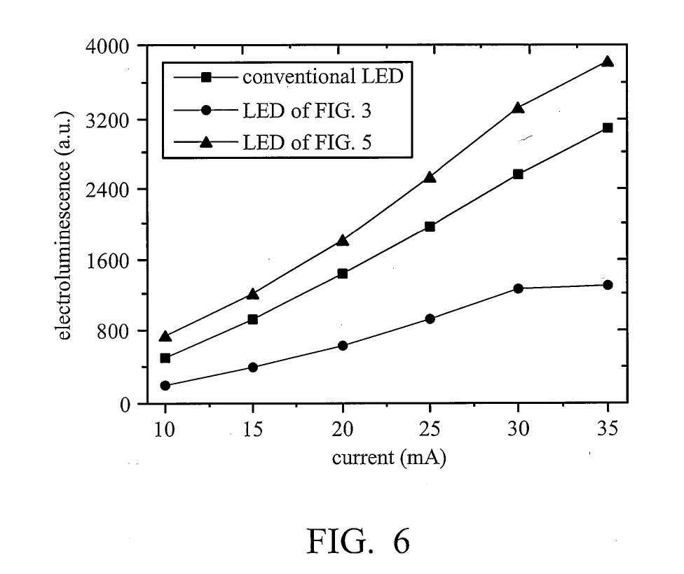

Referring to FIG. 3, which shows a light-emitting device 300 of an embodiment of the invention, an nucleation layer 304, a first type semiconductor layer 306, an active layer 308, a current blocking layer 310 and a second type semiconductor layer 312 are sequentially disposed on a substrate 302 and those elements are summed as a light-emitting element 301 in the embodiment. A current spreading layer 318 including a plurality of strip-shaped structure and an insulating layer 314 are disposed on the second type semiconductor layer 312. A first type electrode 322 and a second type electrode 320 connect the first type semiconductor layer 306 and the second type semiconductor layer 312, respectively. In the embodiment, the first type electrode 322 directly contacts the first type semiconductor layer 306 and the second type electrode 320 indirectly contacts the second type semiconductor layer 312. In more detail, the second type electrode 320 is spaced apart from the second type semiconductor layer 312 by the insulating layer 314, but the second type electrode 320 and the second type semiconductor layer 312 are electrically connected through the current spreading layer 318. In an InGaN based light-emitting diode example, the second type semiconductor layer 312 is a thin p-GaN layer. If the second type electrode 320 and the thin p-GaN layer are widely and directly contacted, current cannot be laterally uniformly diffused into the active layer 308, thus reducing efficiency of electron and hole recombination. The above structural design uses the current spreading layer is also to avoid this issue. Alternatively, a metal layer 316 referred as a surface plasmon coupling element is combined to the light-emitting element 301 in the embodiment. The metal layer 316 is disposed on the strip-shaped structures of the current spreading layer 318 and filled into the gap between the strip-shaped structures of the current spreading layer 318 to contact the second type semiconductor layer 312.

In the embodiment, the substrate 302 is a sapphire substrate, the first type semiconductor layer 306 is a silicon (Si) doped n-GaN layer, the second type semiconductor layer 312 is a magnesium (Mg) doped p-GaN layer, the active layer 308 is an InGaN/GaN quantum-well structure, and the current blocking layer 310 is AlGaN. The n-GaN has higher electron concentration then the hole concentration in the p-GaN and electrons move faster than holes. The current blocking layer 310 blocks electrons to increase light-emitting efficiency. The current spreading layer 318 is a stack layer of gold (Au) and nickel (Ni).

The first type electrode 322 is an n-type electrode, such as a stack layer of titanium (Ti) and aluminum (Al), the second type electrode 320 is a p-type electrode, such as a stack layer of nickel (Ni) and gold (Au), and the insulating layer 314 is formed of silicon oxide. The metal layer 316 preferably is noble metal, such as nickel, silver, gold, titanium or aluminum. The embodiment enhances light emission by coupling between an evanescent field of the surface plasmon and the electric dipole in the active layer 308 to transfer the energy of electrons and holes into the surface plasmon between the metal layer 316 and the second type semiconductor layer 312.

In some cases, surface plasmon energy leakage due to Ohmic contact may occur at the interface between the metal layer 316 and the second type semiconductor layer 312 and energy of surface plasmon may therefore be lost. As shown in FIG. 4, the light-emitting device of FIG. 3 presents lower light-emitting efficiency than the conventional light-emitting device.

According to the issue above, a dielectric layer is interposed between the metal layer and the second type semiconductor layer to reduce energy loss of surface plasmon due to Ohmic contact and efficiently enhances light emission of the light-emitting device with surface plasmon coupling in another embodiment of the invention.

Referring to FIG. 5, which shows a light-emitting device 500 of another embodiment of the invention, a light-emitting element 501 comprises an nucleation layer 504, a first type semiconductor layer 506, an active layer 508, a current blocking layer 510 and a second type semiconductor layer 512 sequentially disposed on a substrate 502, and a current spreading layer 524 including a plurality of the strip-shaped structures and an insulating layer 514 are disposed on the second type semiconductor layer 512.

A first type electrode 526 and a second type electrode 516 connect the first type semiconductor layer 506 and the second type semiconductor layer 512 respectively. In the embodiment, the first type electrode 526 directly contacts the first type semiconductor layer 506 and the second type electrode 516 indirectly contacts the second type semiconductor layer 512. In more detail, the second type electrode 516 is spaced apart from the second type semiconductor layer 512 by the insulating layer 514 but both are electrically connected through the current spreading layer 524. In an important aspect of the invention, the surface plasmon coupling element 522 of the embodiment not only includes a metal layer 520 but further inserts a dielectric layer 518 between the metal layer 520 and the second type semiconductor layer 512. In more detail, the dielectric layer 518 is disposed on the current spreading layer 524 and filled into the gap between the strip-shaped structures of the current spreading layer 524 to contact the second type semiconductor layer, and the metal layer 520 is disposed on the dielectric layer 518.

In the embodiment, the substrate 502 is a sapphire substrate, the first type semiconductor layer 506 is a silicon (Si) doped n-GaN layer, the second type semiconductor layer 512 is a magnesium (Mg) doped p-GaN layer, the active layer 508 is an InGaN/GaN quantum-well structure, the current blocking layer 510 is AlGaN, and the current spreading layer 524 is a stack layer of gold (Au) and nickel (Ni). In the embodiment, the first type electrode 526 is an n-type electrode, such as a stack layer of titanium (Ti) and aluminum (Al), the second type electrode 516 is a p-type electrode, such as a stack layer of nickel (Ni) and gold (Au), and the insulating layer 514 is formed of silicon oxide. The dielectric layer 518 of the surface plasmon coupling element 522 is silicon oxide or silicon nitride and the metal layer 520 preferably is noble metal, such as nickel, silver, gold, titanium or aluminum. The stacked dielectric layer 518 and the second type semiconductor layer 512 preferably has a total thickness less than twice depth of the evanescent field of the noble metal.

The embodiment enhances light emission by coupling between an evanescent field of the surface plasmon and the electric dipole in the active layer 508 to transfer energy of electrons and holes into the surface plasmon between the dielectric layer 518 and the metal layer 520. Alternatively, the embodiment uses the dielectric layer 518 to reduce energy loss of surface plasmon due to Ohmic contact and efficiently enhances light-emitting efficiency.

FIG. 6 shows electroluminescence as a function of current of three LED examples including the LED of FIG. 5, the LED of FIG. 3 and a conventional LED. The three light-emitting devices have light-emitting elements fabricated under the same conditions, in which the first type semiconductor layers are n-GaN layers, the second type semiconductor layers are p-GaN layers, the active layers are InGaN/GaN quantum-well structures, the current blocking layers are (Al_{0.2}Ga_{0.8}N) and the current spreading layers are stack layers of nickel and gold, but the light-emitting device of FIG. 3 uses a silver layer as a surface plasmon element to generate surface plasmon at the interface between the silver layer and the p-GaN layer, the light-emitting device of FIG. 5 uses a silver layer and a silicon nitride layer as a surface plasmon element to generate surface plasmon at the interface between the silver layer and the silicon nitride layer. As shown the FIG. 6, the light-emitting device of FIG. 5 presents about 25%˜50% greater electroluminescence intensity than that of the conventional light-emitting device, but the light-emitting device of FIG. 3 presents lower electroluminescence intensity than that of the conventional light-emitting device due to surface plasmon leakage.

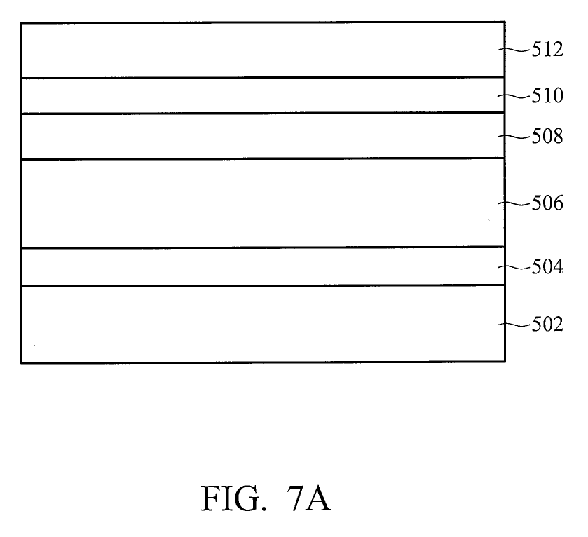

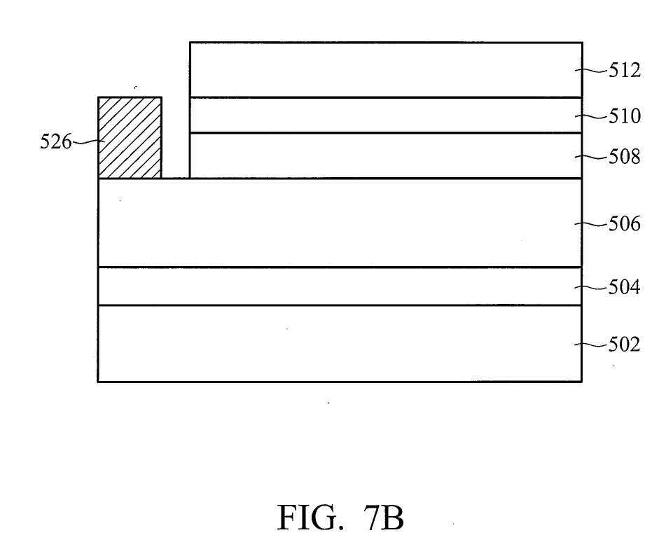

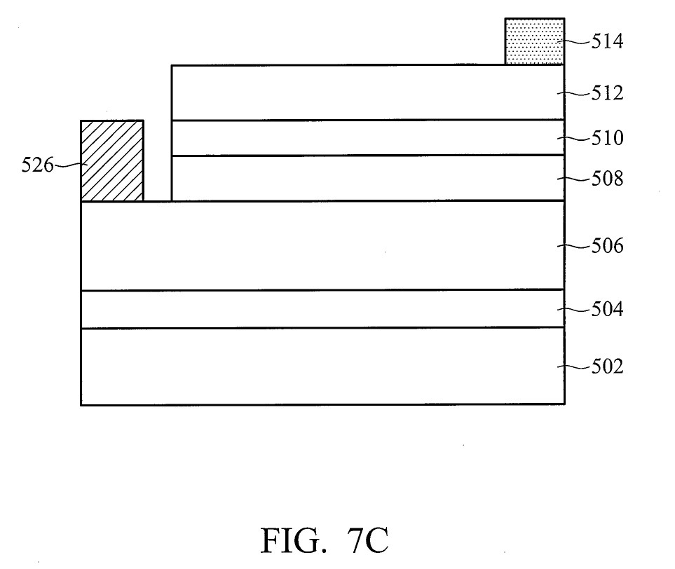

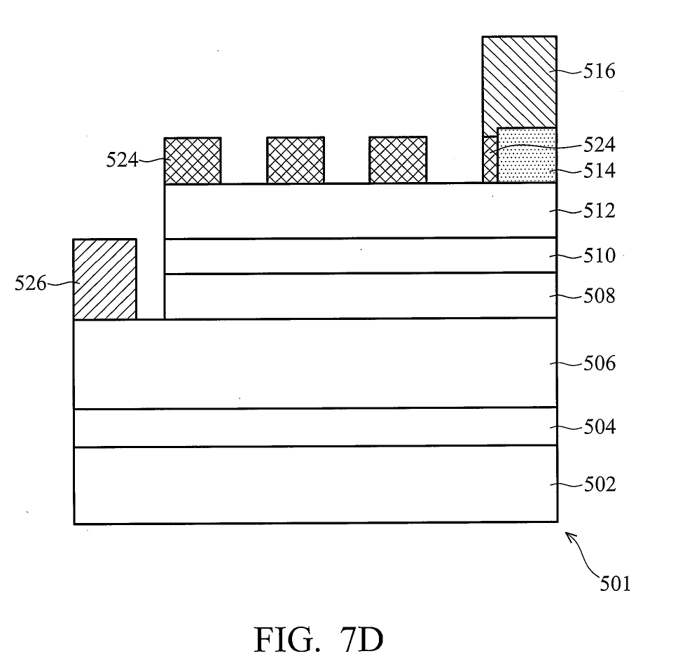

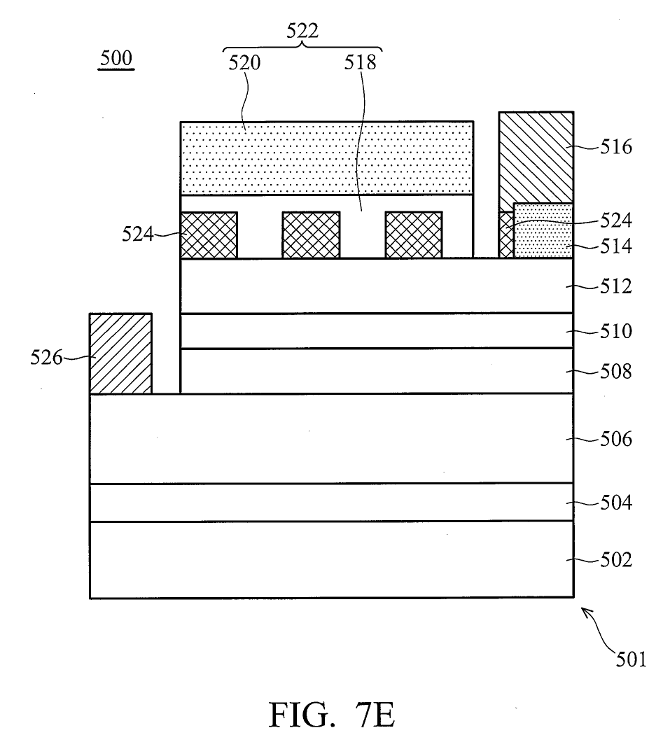

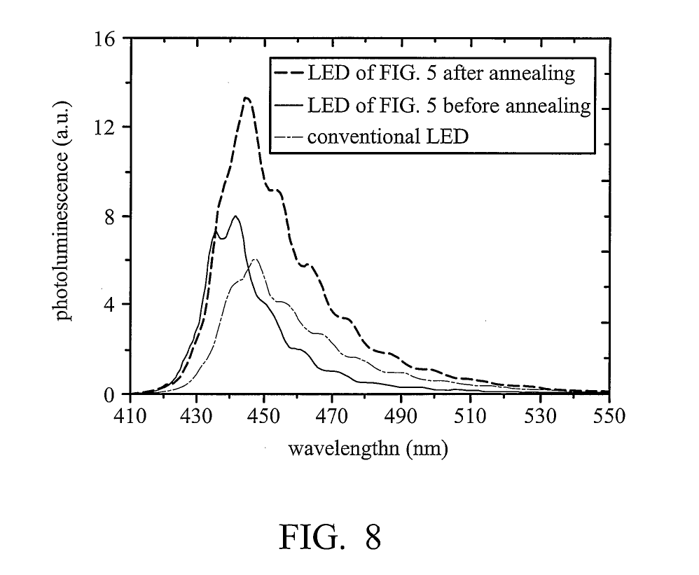

Referring to FIG. 7A˜7E, which show a method for forming the light-emitting diode of FIG. 5, a sapphire substrate 502 is provided and followed by depositing a 25 nm thick nucleation layer 504 by metalorganic chemical vapor deposition (MOCVD) thereon at a temperature of about 535° C. A 2 μm thick n-GaN is deposited by metalorganic chemical vapor deposition (MOCVD) at a temperature of about 1000° C. and with silicon concentration of about 10²⁰/cm⁻³ to form the first type semiconductor layer 506. A 3 nm thick InGaN/GaN quantum well with indium concentration of about 10% is deposited at a temperature of about 760° C., nitrogen flow rate of about 1000 sccm, ammonia flow rate of about 1500 sccm to form the active layer 508. A 10 nm thick (Al_{0.2}Ga_{0.8}N) is deposited to form the current blocking layer 510. A 70 nm thick p-GaN is deposited to form the second type semiconductor layer 512.

Next, a first lithography step is performed with the second type semiconductor layer 512, the current blocking layer 510, the active layer 508, and the first type semiconductor layer 506, and the nucleation layer 504 is etched by inductively coupled plasma reactive ion etching (ICP-RIE) to the substrate 502 to isolate chips and define positions of the light-emitting diodes.

Referring to FIG. 7B, a second lithography step is performed with inductively coupled plasma reactive ion etching (ICP-RIE) to etch the second type semiconductor layer 512, the current blocking layer 510 and the active layer 508, therefore exposing the first type semiconductor layer 506 for defining positions of first type electrodes 526 which will be formed thereafter. Ti and Al are deposited on the exposed first type semiconductor layer 506 and then defined by a third lithography step to form a first type electrode 526. Referring to FIG. 7C, silicon oxide is deposited and then defined by a fourth lithography step to form an insulating layer 514. Referring to FIG. 7D, Ni and Au are deposited on the second type semiconductor layer 512 and then defined by a fifth lithography step to form a strip-shaped current spreading layer 524. Next, Ni and Au are deposited on the insulating layer 514 and the current spreading layer 524 and then defined by a sixth lithography step to form a second type electrode 516. Referring to FIG. 7E, dielectric material, such as silicon oxide or silicon nitride, and metal material, such as Ag and Au, are sequentially deposited on the second type semiconductor layer 512 and the current spreading layer 524 and then defined by a seventh lithography step to form a dielectric layer 518 and a metal layer 520 of a surface plasmon coupling element 522.

Alternatively, after forming the metal layer 520, the embodiment can further anneals the metal layer 520 to form an nanostructure for enhancing luminance of the light-emitting device. FIG. 8 shows photoluminescence as a function of wavelength of three LED examples including the LED of FIG. 5 before annealing, the LED of FIG. 5 after annealing and a conventional LED. As shown in the figure, the LED after annealing presents higher photoluminescence than the LED before annealing and no matter if the LED of FIG. 5 is annealed or not, it presents higher photoluminescence than the conventional LED.

The difference of fabrication between the LED of FIG. 3 and FIG. 5 is that a dielectric layer is not formed between the second type semiconductor layer and the metal layer in the LED of FIG. 3, but the dielectric layer is formed in the LED of FIG. 5. A person in the art can realize the fabrication of the LED of FIG. 5, according the fabrication described in accordance the LED of FIG. 3 and thus the fabrication is not illustrated herein.

Referring to FIG. 3 again, it is noted that the distance between the active layer 308 and the metal layer 316 in the LED is preferably less than depth of the evanescent field of the surface plasmon to more efficiently coupling the electron hole pairs in the active layer 308 to form a surface plasmon. However, depth of the evanescent field of a surface plasmon is generally less than thickness of the p-GaN layer 312. Thus, thickness of the p-GaN layer 312 is required to be reduced when fabricating the LED device with surface plasmon coupling elements, but the p-GaN layer 312 typically having hole concentration less than 10¹⁸ cm⁻³ that cannot be too thin because this may generate hole diffusion and resistivity rising issues.

Therefore, the surface plasmon coupling elements are formed on the n-GaN layer to further improve emitting efficiency in the embodiment. Because the number of the major carriers in the n-GaN layer is much more than that in the p-GaN layer, thinning of the n-GaN layer does not easily cause carrier diffusion and resistivity rising issues. The embodiment reduces thickness of the n-GaN layer and forms a surface plasmon coupling element thereon to improve emitting efficiency and eliminate the issues described.

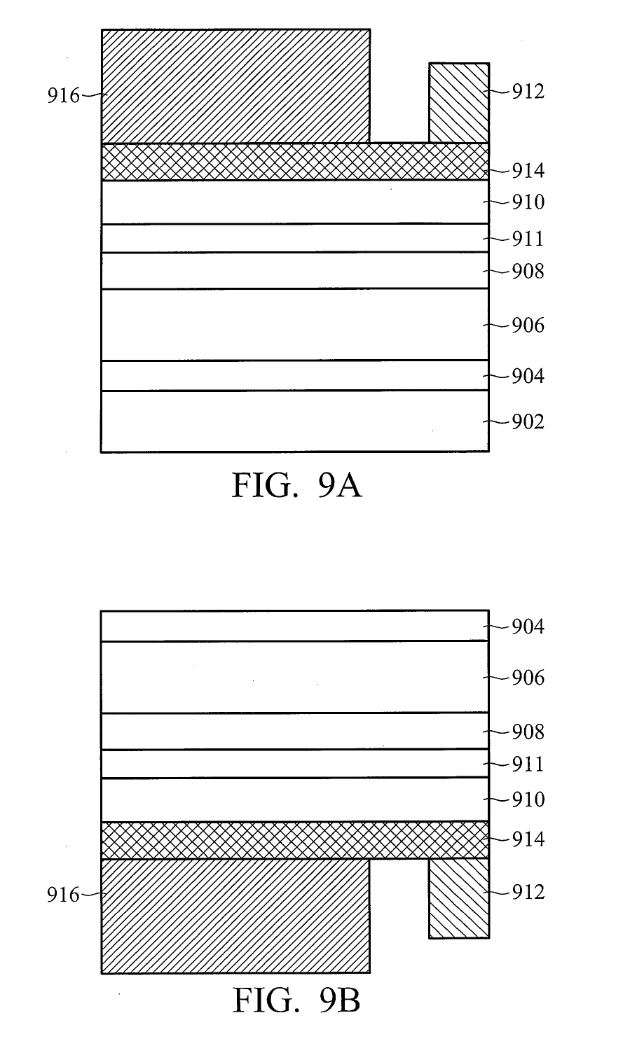

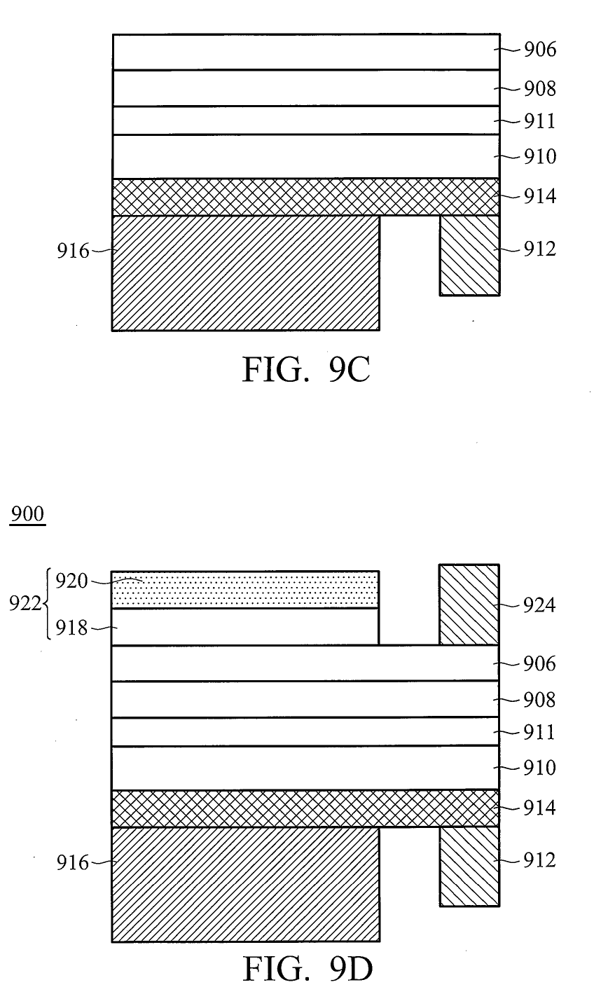

FIG. 9A˜FIG. 9D illustrate process for fabricating a transmissive light-emitting device of an embodiment of the invention. First, referring to FIG. 9A, a substrate 902 such as sapphire is provided and an nucleation layer 904 is deposited by metalorganic chemical vapor deposition (MOCVD). Next, an n-GaN layer with a thickness of about 2 μm is deposited on the nucleation layer by MOCVD at a temperature of about 1000° C. and silicon doping concentration of about 10²⁰/cm⁻³ to form an n-type semiconductor layer 906. An InGaN/GaN quantum-well structure is deposited at a temperature of about 760° C., nitrogen flow rate of about 1000 sccm and ammonia gas flow rate of about 1500 sccm to form an active layer 908, wherein the InGaN well layer has a thickness of about 3 nm, the GaN barrier layer has a thickness of about 10 nm and the indium concentration is about 10%. Next, Al_{0.2}Ga_{0.8}N with a thickness of about 20 nm is deposited to form a current blocking layer 911. P—GaN with a thickness of about 200 nm is deposited to form a p-type semiconductor layer 910. A stack layer 914 including nickel and gold is deposited on the p-type semiconductor layer 910 to form a p-type current spreading layer and a p-type electrode 912 is then formed on the p-type current spreading layer. Thereafter, the p-type current spreading layer is combined with a copper supporting member 916.

Referring to FIG. 9B, the device formed described is placed up-side down and the substrate 902 is removed from the nucleation layer 904 by laser lift-off technique. Referring to FIG. 9C, the nucleation layer 904 and the n-type semiconductor layer 906 is etched sequentially by inductively coupled plasma reactive ion etching (ICP-RIE) for the n-type semiconductor layer 906 to be recessed to about 5 nm˜200 nm thick (preferably is about 10 nm˜40 nm thick). Etching the n-type semiconductor layer 906 is to make the layer thinner for reducing distance between a surface plasmon coupling element which will be formed thereafter and the active layer 908 (preferably less than depth of evanescent field of surface plasmon) to improve coupling strength of the quantum well and the surface plasmon for increasing emitting efficiency.

Referring to FIG. 9D, a dielectric layer 918, such as silicon oxide or silicon nitride and with a thickness of about 10 nm, is deposited on the etched n-type semiconductor layer 906 by plasma enhanced chemical vapor deposition (PECVD). Next, a metal layer 920, such as Au, Ag or Al, is deposited on the dielectric layer 918. In the embodiment, the dielectric layer 918 and the metal layer 920 are used as a surface plasmon coupling element 922, and the dielectric layer 918 is to reduce Ohmic contact loss of the surface plasmon to more efficiently increase emitting efficiency of the light-emitting device by coupling of surface plasmon with quantum well. Thereafter, a thermal treating step is performed for the metal layer 920 to form nano-structure by rapid thermal annealing (RTA). An n-type electrode 924 is formed on the n-type semiconductor layer 906 by evaporation. It is noted that the n-type electrode 924 and the p-type electrode 912 is on the opposite sides of the transmissive light-emitting device in the embodiment.

The surface plasmon coupling element 922 is formed on the n-type semiconductor layer 906 which is further etched to reduce thickness. Thus, the distance between the quantum well and the surface plasmon coupling element 922 in the LED can be less than depth of evanescent field of surface plasmon to more efficiently transfer the electron-hole energy in the quantum well into the surface plasmon and increase emitting efficiency therefore.

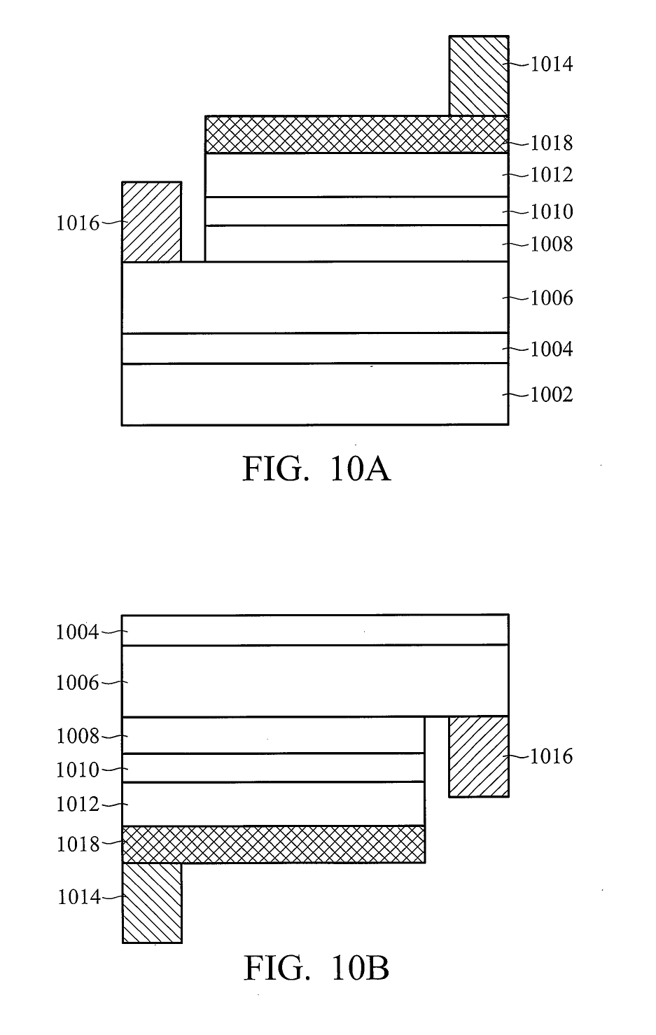

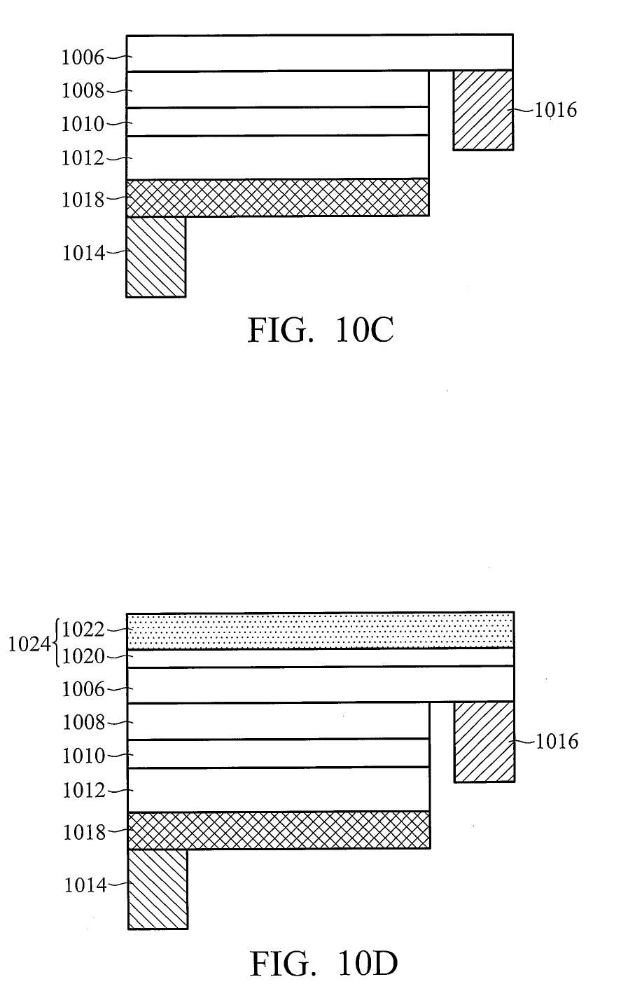

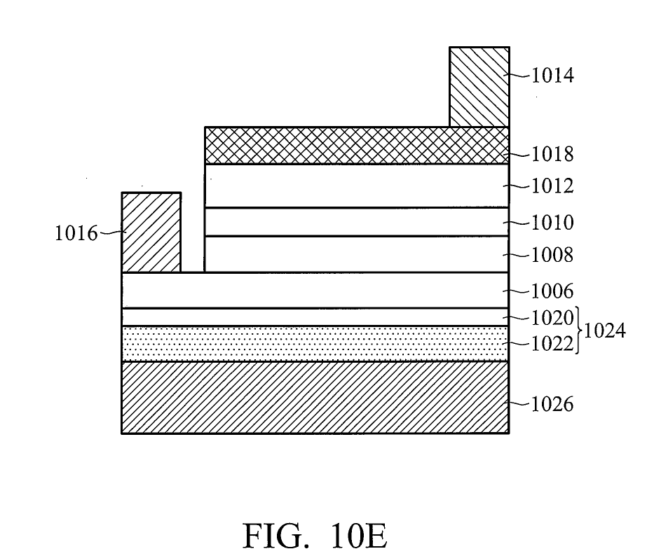

FIG. 10A˜FIG. 10E illustrate process for fabricating a reflective light-emitting device of another embodiment of the invention. First, referring to FIG. 10A, a substrate 1002 such as sapphire is provided and an nucleation layer 1004 with a thickness of about 25 nm is deposited by metalorganic chemical vapor deposition (MOCVD) at a temperature of about 535° C. Next, an n-GaN layer with a thickness of about 2 μm is deposited on the nucleation layer by MOCVD at a temperature of about 1000° C. and silicon doping concentration of about 1020/cm−3 to form an n-type semiconductor layer 1006. An InGaN/GaN quantum-well structure is deposited at a temperature of about 760° C., nitrogen flow rate of about 1000 sccm and ammonia gas flow rate of about 1500 sccm to form an active layer 1008, wherein the InGaN well layer has a thickness of about. 3 nm, the GaN barrier layer has a thickness of about 10 nm and the indium concentration is about 10%. Next, Al_{0.2}Ga_{0.8}N with a thickness of about 20 nm is deposited to form a current blocking layer 1010. P—GaN with a thickness of about 200 nm is deposited to form a p-type semiconductor layer 1012.

Next, a lithography process is performed and the p-type semiconductor layer 1012, the current blocking layer 1010 and the active layer 1008 are sequentially etched by RIE to expose the n-type semiconductor layer 1006. A stack layer including Ti and Al is deposited on the exposed n-type semiconductor layer 1006 and then patterned to form an n-type electrode 1016. Thereafter, a stack layer including Ni and Au is deposited on the exposed p-type semiconductor layer 1012 and then patterned to form a current spreading layer 1018 and a p-type electrode 1014. It is noted that the n-type electrode 1016 and the p-type electrode 1014 is on the same side of the reflective light-emitting device in the embodiment.

Referring to FIG. 10B, the device formed described is placed up-side down and the substrate 1002 is removed from the nucleation layer 1004 by laser lift-off technique. Referring to FIG. 10C, the nucleation layer 1004 and the n-type semiconductor layer 1006 is etched sequentially by inductively coupled plasma reactive ion etching (ICP-RIE) for the n-type semiconductor layer 1006 to be recessed to about 5 mm˜200 nm thick (preferably is about 10 nm˜40 nm thick). Referring to FIG. 10D, a dielectric layer 1020, such as silicon oxide or silicon nitride and with a thickness of about 10 nm, is deposited on the etched n-type semiconductor layer 1006 by plasma enhanced chemical vapor deposition (PECVD). Next, a metal layer 1022, such as Au, Ag or Al, is deposited on the dielectric layer 1020. In the embodiment, the dielectric layer 1020 and the metal layer 1022 are used as a surface plasmon coupling element 1024. Referring to FIG. 10E, the device is placed up side down again and the metal layer 1022 is combined with a copper supporting member 1026.

In the embodiment, the metal layer 1022 is also formed on the n-type semiconductor layer 1006 which is further etched to reduce thickness. Thus, the distance between the quantum well and the surface plasmon coupling element 1024 in the LED can be less than depth of evanescent field of surface plasmon to more efficiently coupling the electron-hole energy in the quantum well into the surface plasmon and increasing emitting efficiency therefore.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A light-emitting device, comprising:
a light-emitting element; and
a surface plasmon coupling element connected to the light-emitting element, wherein the surface plasmon coupling element comprises a dielectric layer connected to the light-emitting element and a metal layer on the dielectric layer.

2. The light-emitting device as claimed in claim 1, wherein the light-emitting element comprises a first type semiconductor layer, an active layer on the first type semiconductor layer and a second type semiconductor layer on the active layer.

3. The light-emitting device as claimed in claim 1, wherein the metal layer comprises Ni, Ag, Au, Ti or Al.

4. The light-emitting device as claimed in claim 1, wherein the dielectric layer comprises silicon nitride or silicon oxide.

5. The light-emitting device as claimed in claim 2, wherein the first type semiconductor layer is n-GaN and the second type semiconductor layer is p-GaN.

6. The light-emitting device as claimed in claim 2, further comprising a current spreading layer between the second type semiconductor layer and the surface plasmon coupling element, and the current spreading layer is strip-shaped.

7. The light-emitting device as claimed in claim 6, further comprising a first type electrode connected to the first type semiconductor layer and a second type electrode connected to the current spreading layer, and the second type electrode is isolated from the second type semiconductor layer by an insulating layer.

8. The light-emitting device as claimed in claim 7, wherein the insulating layer comprises silicon nitride or silicon oxide.

9. The light-emitting device as claimed in claim 2, further comprising a current blocking layer between the second type semiconductor layer and the active layer.

10. A light-emitting diode, comprising:
an active layer between an n-type semiconductor layer and a p-type semiconductor layer; and
a surface plasmon coupling element adjacent to the n-type semiconductor layer.

11. The light-emitting diode as claimed in claim 10, wherein the surface plasmon coupling element comprises a dielectric layer connected to the n-type semiconductor layer and a metal layer on the dielectric layer.

12. The light-emitting device as claimed in claim 11, wherein the metal layer comprises Ni, Ag, Au, Ti or Al.

13. The light-emitting diode as claimed in claim 11, wherein the dielectric layer comprises silicon nitride or silicon oxide.

14. The light-emitting diode as claimed in claim 10, wherein the n-type semiconductor layer is about 5 nm˜200 nm thick.

15. The light-emitting diode as claimed in claim 10, wherein the metal layer is an nano-structure.

16. A light-emitting diode, comprising:
a first type semiconductor layer;
an active layer disposed on the first type semiconductor layer;
a second type semiconductor layer disposed on the active layer;
a current spreading layer including a plurality of strip-shaped structures disposed on the second type semiconductor layer; and
a surface plasmon coupling element disposed on the current spreading layer and filled into a gap between the strip-shaped structures of the current spreading layer.

17. The light-emitting diode as claimed in claim 16, wherein the surface plasmon coupling element comprises a dielectric layer filled into the gap between the strip-shaped structures of the current spreading layer and a metal layer on the dielectric layer.

18. The light-emitting diode as claimed in claim 16, wherein further comprising an insulating layer on the second type semiconductor layer.

19. The light-emitting diode as claimed in claim 18, further comprising a second type electrode spaced apart from the second type semiconductor layer by the insulating layer but both are electrically connected through the current spreading layer.

20. The light-emitting diode as claimed in claim 16, wherein the current spreading layer is a stack layer of gold (Au) and nickel (Ni).
